(19) United States
(12) Patent Application Publication
(10) Pub. No.: US 2014/0110804 A1
(43) Pub. Date: Apr. 24, 2014

(54) MAGNETORESISTIVE DEVICE AND METHOD FOR FORMING THE SAME

(71) Applicant: Agency for Science, Technology and Research, Singapore (SG)

(72) Inventors: Guchang Han, Singapore (SG); Jacob ChenChen Wang, Singapore (SG); Michael Tran, Singapore (SG); Kwaku Eason, Singapore (SG)

(73) Assignee: Agency for Science, Technology and Research, Singapore (SG)

(21) Appl. No.: 14/057,198

(22) Filed: Oct. 18, 2013

Related U.S. Application Data
(60) Provisional application No. 61/715,340, filed on Oct. 18, 2012.

(51) Int. Cl. H01L 43/02; H01L 43/12

(52) U.S. Cl. CPC H01L 43/02; H01L 43/12
USPC 257/421; 438/3

(57) ABSTRACT

According to embodiments of the present invention, a magnetoresistive device is provided. The magnetoresistive device includes a free magnetic layer structure having a variable magnetization orientation, and a synthetic antiferromagnetic layer structure including at least three ferromagnetic layers arranged one over the other and antiferromagnetically coupled, each ferromagnetic layer having a fixed magnetization orientation, wherein the free magnetic layer structure and the synthetic antiferromagnetic layer structure are arranged one over the other. According to further embodiments of the present invention, a method for forming a magnetoresistive device is also provided.

### CROSS-REFERENCE TO RELATED APPLICATION

This application claims the benefit of priority of U.S. provisional application No. 61/715,340, filed 18 Oct. 2012, the content of it being hereby incorporated by reference in its entirety for all purposes.

### TECHNICAL FIELD

Various embodiments relate to a magnetoresistive device and a method for forming the magnetoresistive device.

### BACKGROUND

For applications in a recording head and a magnetoresistive random-access memory (MRAM), giant magnetoresistive (GMR) or tunnel magnetoresistive (TMR) devices are usually composed of a storage layer (also termed as a free layer, FL) and a reference layer (RL).

FIG. 1A shows a schematic diagram of a conventional device (GMR device or TMR device) 100 having a stack structure with a simple or single synthetic antiferromagnetic (SAF) structure 102. The term “single SAF structure” means a conventional three-layered SAF structure having two ferromagnetic (FM) layers and one antiferromagnetic coupling (AFC) layer. The device 100 includes a seed layer 104, an antiferromagnetic (AFM) pinning layer 106, a pinned layer (PL) 108, an antiferromagnetic coupling (AFC) layer 110, a reference layer (RL) 112, a spacer layer 114, a free layer (FL) 116, and a cap layer 118. The pinned layer 108, the AFC layer 110, and RL 112 form the SAF structure 102. PL 108 and RL 112 have magnetization orientations that are anti-aligned (i.e. antiferromagnetically coupled), as indicated by the respective oppositely directed arrows 120a, 120b for an in-plane magnetization device or the respective oppositely directed arrows 122a, 122b for a perpendicular magnetization device. The magnetization of RL 112 is fixed by the synthetic antiferromagnetic (SAF) pinning structure 102, where RL 112 is strongly coupled through the AFC layer 110. The SAF pinning structure 102 is pinned by the AFM pinning layer 106. This simple or single SAF structure 102 is used to increase the pinning stability to provide high pinning field, and to reduce or remove the offset field from RL 112. The stability of the SAF structure 102 may be defined by the exchange coupling (or pinning) field, Hₑₓ, which is inversely proportional to the difference between the magnetic thickness ((Mᵣt)_{P}) of the PL 108 and the magnetic thickness ((Mᵣt)_{R}) of the RL 112, as provided below:

$${H}_{ex} ∝ \frac{J}{{( {M}_{r} t )}_{P} - {( {M}_{r} t )}_{R}} , \qquad ( Equation 1 )$$

where Mᵣ is the remanent magnetization, t is the thickness and J is the exchange strength between PL 108 and AFM layer 106. In order to realize the above-mentioned advantages, the magnetic thickness of RL 112, ((Mᵣt)_{R}), and the magnetic thickness of PL 108, ((Mᵣt)_{P}), should be as close as possible to each other in order to provide a high exchange coupling field, Hₑₓ. In order to maximize SAF stability, M_{rP}=M_{rR} and t_{P}=t_{R}.

The balanced magnetic configuration of the SAF structure 102 also helps to reduce the offset field generated by the SAF structure 102 on FL 116. However, as the device size shrinks to accommodate storage density increment, the offset field in this balanced magnetic configuration of the SAF structure 102 increases significantly.

FIG. 1B shows the stray fields of conventional devices having a stack structure with a simple synthetic antiferromagnetic (SAF) structure. For ease of understanding and clarity, only the free layer (FL), the reference layer (RL) and the pinned layer (PL) are shown. FIG. 1B shows a device 130a with in-plane anisotropy, having FL 132a and a SAF structure having RL 134a and PL 136a, as well as a device 130b with perpendicular anisotropy, having FL 132b and a SAF structure having RL 134b and PL 136b. The stray fields, indicated as “H”, are represented by the dashed arrows. As the SAF lateral-size decreases, there is a large increase in the stray field. The large stray field adversely affects the free layer (FL) 132a, 132b, which are supposed to be free from external magnetic bias.

FIG. 1C illustrates the effect of a stray field on a free layer. The stray field that is present will cause a shift in the hysteresis loop (e.g. magnetization-field (MH) loop) 138 of the free layer (as shown in the right figure, compared to the left figure), resulting in changes to the coercivity (H_{c}). The offset field (also termed as the bias field), H_{b}, is defined as the field shift of the free layer switching, or in other words the offset field causes an offset or shift in the magnetization orientation of the free layer.

FIG. 1D shows a plot 140 of the stray field of a simple SAF structure with in plane magnetization, illustrating the average stray field on the free layer due to in-plane magnetization reference layer with a SAF structure. For comparison, the average stray field on the free layer due to a single in-plane magnetization reference layer, without a SAF structure, is also shown. The thickness of the reference layer in both cases is the same. FIG. 1E shows a plot 142 of the stray field of a simple SAF structure with perpendicular magnetization, illustrating the average stray field on the free layer due to perpendicular magnetization reference layer with a SAF structure. For comparison, the average stray field on the free layer due to a single perpendicular magnetization reference layer, without a SAF structure, is also shown. The thickness of the reference layer in both cases is the same.

In FIGS. 1D and 1E, the results labeled as “x-line-SAF avg” and “x-line-NOSAF avg” are the stray fields averaged over a 1d line along the x direction indicated in FIG. 1D, for respective devices with a SAF structure and without a SAF structure. The results labeled as “2D area-SAF avg” and “2D area-NOSAF avg” are the stray field values averaged over the entire 2D plane of the free layer, for respective devices with a SAF structure and without a SAF structure.

As shown in FIGS. 1D and 1E, for both in-plane and perpendicular magnetization, the stray field at the free layer increases from several Oersteds to several hundreds of Oersteds as the size decreases. Such a large offset field will induce a signal-to-noise ratio (SNR) reduction in the read head, and also induce read/write errors as well as the reduction of data retention in MRAM and thus, the offset field has to be reduced or removed.

The offset field can also be reduced using an unbalanced SAF, where the magnetic thicknesses of the reference layer and the pinned layer are unbalanced, e.g. (Mrt)_{P}>(Mrt)_{R}. However, the unbalanced SAF will also cause a reduction in the exchange field Hₑₓ, as can be seen from Equation 1 when (Mᵣt)_{P}≠(Mᵣt)_{R}, thereby resulting in pinning instability of the SAF magnetization. An unbalanced SAF structure can be achieved by changing the respective thicknesses of the reference layer and the pinned layer. FIG. 1F shows a plot 150 of the stray field of a conventional device having a simple unbalanced synthetic antiferromagnetic (SAF) structure with perpendicular magnetization. The result 152 is the stray field averaged over a 1d line along an x direction similar to that indicated in FIG. 1D, while the result 154 is the stray field averaged over the entire 2D plane of the free layer. The x-axis shows the ratio of the thicknesses, t, of the two ferromagnetic layers (SAF2, SAF1) of the unbalanced SAF structure, where SAF1 is the ferromagnetic layer proximal to the free layer, while SAF2 is the ferromagnetic layer distal to the free layer. The respective magnetizations, Mᵣ, for SAF2 and SAF1 are the same.

### SUMMARY

According to an embodiment, a magnetoresistive device is provided. The magnetoresistive device may include a free magnetic layer structure having a variable magnetization orientation, and a synthetic antiferromagnetic layer structure including at least three ferromagnetic layers arranged one over the other and antiferromagnetically coupled, each ferromagnetic layer having a fixed magnetization orientation, wherein the free magnetic layer structure and the synthetic antiferromagnetic layer structure are arranged one over the other.

According to an embodiment, a method for forming a magnetoresistive device is provided. The method may include forming a free magnetic layer structure having a variable magnetization orientation, and forming a synthetic antiferromagnetic layer structure including at least three ferromagnetic layers arranged one over the other and antiferromagnetically coupled, each ferromagnetic layer having a fixed magnetization orientation, wherein the free magnetic layer structure and the synthetic antiferromagnetic layer structure are arranged one over the other.

### BRIEF DESCRIPTION OF THE DRAWINGS

In the drawings, like reference characters generally refer to like parts throughout the different views. The drawings are not necessarily to scale, emphasis instead generally being placed upon illustrating the principles of the invention. In the following description, various embodiments of the invention are described with reference to the following drawings, in which:

FIG. 1A shows a schematic diagram of a conventional device having a stack structure with a simple synthetic antiferromagnetic (SAF) structure.

FIG. 1B shows the stray fields of conventional devices having a stack structure with a simple synthetic antiferromagnetic (SAF) structure.

FIG. 1C illustrates the effect of a stray field on a free layer.

FIGS. 1D and 1E show plots of the stray field of a simple SAF structure with in plane magnetization and perpendicular magnetization respectively.

FIG. 1F shows a plot of the stray field of a conventional device having a simple unbalanced synthetic antiferromagnetic (SAF) structure with perpendicular magnetization.

FIG. 2A shows a schematic diagram of a magnetoresistive device, according to various embodiments.

FIG. 2B shows a flow chart illustrating a method for manufacturing a magnetoresistive device, according to various embodiments.

FIG. 3 shows a schematic diagram of a magnetoresistive device, according to various embodiments.

FIGS. 4A and 4B show respective plots of simulated offset fields for an in-plane magnetic anisotropy device and a perpendicular magnetic anisotropy device, for different thickness combinations of the synthetic antiferromagnetic (SAF) multilayer, according to various embodiments.

FIGS. 4C and 4D show respective plots of stray fields at the middle of a free layer of a perpendicular magnetic anisotropy device, for different SAF structures for a 20 nm device and a 65 nm device respectively, according to various embodiments.

FIG. 4E shows a plot of simulated offset field for a perpendicular magnetic anisotropy device, for different thickness combinations of the synthetic antiferromagnetic (SAF) multilayer, according to various embodiments.

FIG. 5A shows a schematic diagram of a magnetoresistive device with a cancellation layer, according to various embodiments.

FIG. 5B illustrates the effect of a field produced by a cancellation layer on a stray field produced by a SAF multilayer structure, according to various embodiments.

FIG. 5C shows a plot of stray field of a magnetoresistive device without a cancellation layer, according to various embodiments.

FIG. 6A shows an initialization scheme for a magnetoresistive device, according to various embodiments.

FIG. 6B shows an initialization scheme for a magnetoresistive device having a SAF multilayer structure having an even number of FM layers, according to various embodiments.

FIG. 6C shows an initialization scheme for a magnetoresistive device, according to various embodiments.

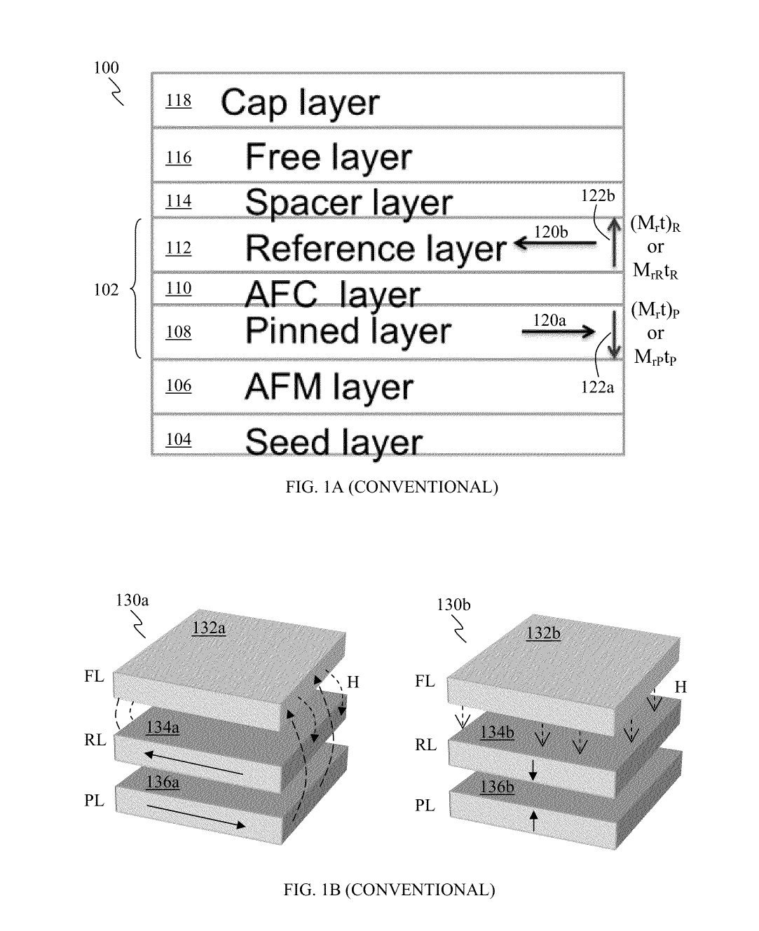

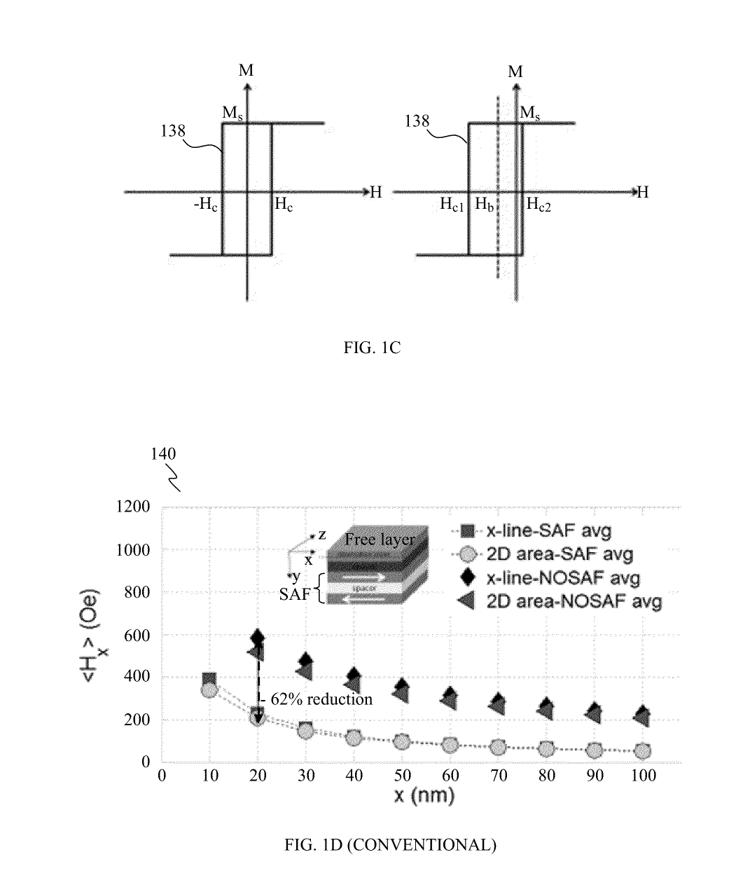

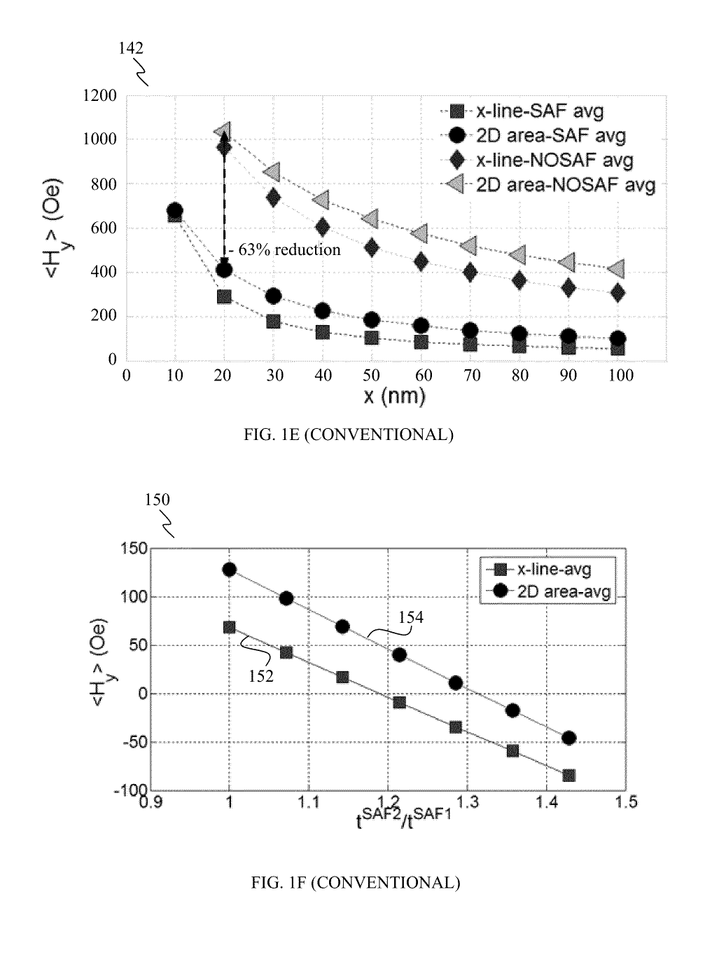

### DETAILED DESCRIPTION

The following detailed description refers to the accompanying drawings that show, by way of illustration, specific details and embodiments in which the invention may be practiced. These embodiments are described in sufficient detail to enable those skilled in the art to practice the invention. Other embodiments may be utilized and structural, logical, and electrical changes may be made without departing from the scope of the invention. The various embodiments are not necessarily mutually exclusive, as some embodiments can be combined with one or more other embodiments to form new embodiments.

Embodiments described in the context of one of the methods or devices are analogously valid for the other method or device. Similarly, embodiments described in the context of a method are analogously valid for a device, and vice versa.

Features that are described in the context of an embodiment may correspondingly be applicable to the same or similar features in the other embodiments. Features that are described in the context of an embodiment may correspondingly be applicable to the other embodiments, even if not explicitly described in these other embodiments. Furthermore, additions and/or combinations and/or alternatives as described for a feature in the context of an embodiment may correspondingly be applicable to the same or similar feature in the other embodiments.

In the context of various embodiments, the articles “a”, “an” and “the” as used with regard to a feature or element includes a reference to one or more of the features or elements.

In the context of various embodiments, the phrase “at least substantially” may include “exactly” and a reasonable variance.

In the context of various embodiments, the term “about” or “approximately” as applied to a numeric value encompasses the exact value and a reasonable variance.

As used herein, the term “and/or” includes any and all combinations of one or more of the associated listed items.

As used herein, the phrase of the form of “at least one of A or B” may include A or B or both A and B. Correspondingly, the phrase of the form of “at least one of A or B or C”, or including further listed items, may include any and all combinations of one or more of the associated listed items.

Various embodiments may relate to giant magnetoresistive (GMR) and/or tunnel magnetoresistive (TMR) devices for magnetoresistive random-access memory (MRAM) and read head applications.

Various embodiments may provide an approach for offset field reduction and improvement of pinning stability with synthetic antiferromagnetic (SAF) multilayer.

Various embodiments may provide a synthetic antiferromagnetic (SAF) multilayer structure having more than three layers, which may be composed of more than two ferromagnetic (FM) layers and more than one antiferromagnetic coupling (AFC) layer, to reduce the offset field on the free layer without sacrificing the stability of the SAF multilayer. An antiferromagnetic (AFM) layer may be used to pin the SAF multilayer structure. In order to increase the stability of the SAF multilayer, the vector sum of the magnetic moments in the SAF multilayer should be close to zero. In other words, the effective magnetic thickness of the SAF multilayer should be close to zero. The thickness of each FM layer of the SAF multilayer may be selected to provide a minimum offset field for the free layer switching. A cancellation layer may be added for further compensation of the offset field.

Various embodiments may provide one or more of the following: (1) a small stray field may be obtained using a SAF multilayer structure having at least three (e.g. an uneven number greater than two; e.g. an even number greater than two; e.g. three, four, five, six, seven, eight, etc.) ferromagnetic layers; (2) a high stability of the SAF pinning structure may be maintained; (3) the field cancellation layer may enable magnetoresistive devices (e.g. magnetic tunnel junction (MTJ) devices) scalable down to very small size; or (4) simple magnetization initialization, for example for the SAF structure and/or the cancellation layer.

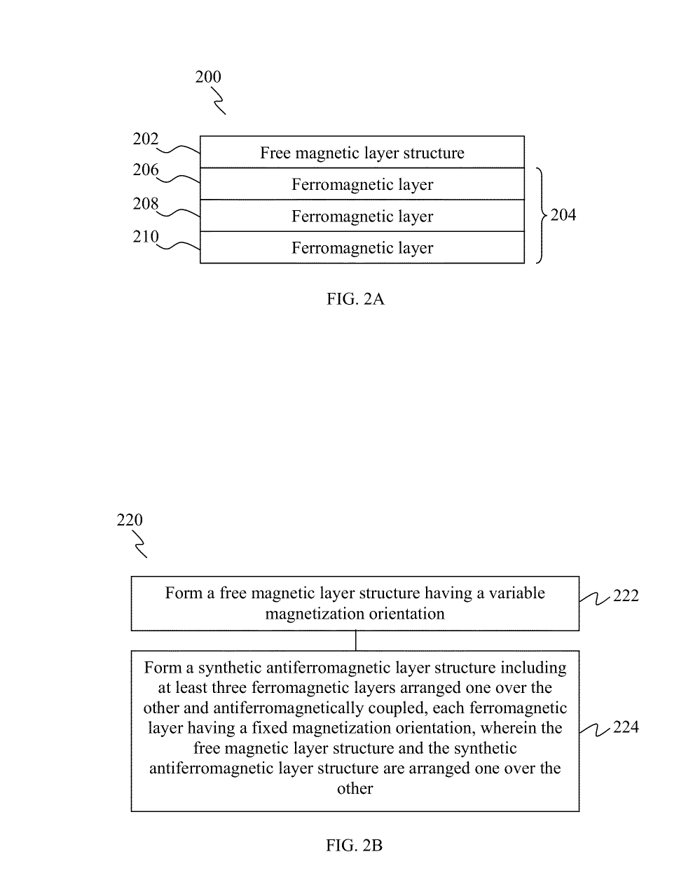

FIG. 2A shows a schematic diagram of a magnetoresistive device 200, according to various embodiments. The magnetoresistive device 200 includes a free magnetic layer structure 202 having a variable magnetization orientation, and a synthetic antiferromagnetic layer structure 204 including at least three ferromagnetic layers 206, 208, 210 arranged one over the other and antiferromagnetically coupled, each ferromagnetic layer 206, 208, 210 having a fixed magnetization orientation, wherein the free magnetic layer structure 202 and the synthetic antiferromagnetic layer structure 204 are arranged one over the other.

In other words, the magnetoresistive device 200 may have a layer stack structure having a free magnetic layer (FL) structure 202 that may serve as a storage layer, and a synthetic antiferromagnetic (SAF) layer structure 204 having a multilayer arrangement with at least three ferromagnetic (FM) layers 206, 208, 210. The free magnetic layer structure 202 may have a magnetization orientation that may be variable or switchable between two possible directions, for example in response to an electrical or magnetic signal applied to the magnetoresistive device 200. The free magnetic layer structure 202 may be arranged over the synthetic antiferromagnetic layer structure 204 as shown in FIG. 2A. However, it should be appreciated that the synthetic antiferromagnetic layer structure 204 may instead be arranged over the free magnetic layer structure 202.

Each of the three ferromagnetic layers 206, 208, 210 may have a magnetization orientation that is fixed, or in other words each magnetization orientation generally points in a single fixed or pinned direction. This may mean that each ferromagnetic layer 206, 208, 210 may be a fixed magnetic layer structure having a fixed magnetization orientation.

The three ferromagnetic layers 206, 208, 210 may be arranged one over the other. This may mean that one ferromagnetic layer 206 may be arranged proximal to the free magnetic layer structure 202, another ferromagnetic layer 210 may be arranged distal to the free magnetic layer structure 202, while the remaining ferromagnetic layer 208 may be arranged between the proximal ferromagnetic layer 206 and the distal ferromagnetic layer 210. The ferromagnetic layer 206 may be a reference layer (RL), while each of the ferromagnetic layers 208, 210 may be a pinned layer (PL). In this way, the ferromagnetic layer 206 may act as a reference for the free magnetic layer structure 202, e.g. the magnetization orientation of the free magnetic layer structure 202 relative to the magnetization orientation of the ferromagnetic layer 206 may define the “value” stored in the free magnetic layer structure 202. For example, when the respective magnetization orientations of the free magnetic layer structure 202 and the ferromagnetic layer 206 are oriented parallel (P state) relative to each other (oriented in the same direction), the magnetoresistive device 200 may have a low resistivity, and hence low resistance, to define a “0” state or value. When the respective magnetization orientations of the free magnetic layer structure 202 and the ferromagnetic layer 206 are anti-parallel (AP state) relative to each other (oriented in opposite directions), the magnetoresistive device 200 may have a high resistivity, and hence high resistance, to define a “1” state or value.

For the synthetic antiferromagnetic layer structure 204, adjacent two ferromagnetic layers may be antiferromagnetically coupled, e.g. through an antiferromagnetic coupling (AFC) layer. In other words, the respective magnetization orientations of the adjacent two ferromagnetic layers may be anti-aligned or anti-parallel (oppositely directed). For example, the ferromagnetic layer 208 may be antiferromagnetically coupled with each of the ferromagnetic layers 206, 210. Therefore, the magnetization orientation of the ferromagnetic layer 208 may be anti-aligned (oriented anti-parallel) to the respective magnetization orientations of the ferromagnetic layers 206, 210. This also means that the respective magnetization orientations of the ferromagnetic layers 206, 210 may be aligned or oriented parallel to each other.

In the context of various embodiments, the term “free magnetic layer structure” may mean a magnetic layer structure having a variable or switchable magnetization orientation. In other words, the magnetization orientation may be varied or switched, for example in response to an electrical signal (e.g. current) or a magnetic field applied to the magnetoresistive device 200. The magnetization orientation of the free magnetic layer structure may be varied, depending on the degree or amount of the magnetization reversal field (or current). The free magnetic layer structure may include a soft ferromagnetic material. The soft ferromagnetic material may be receptive to magnetization and demagnetization (i.e. easily magnetized and demagnetized), and may have a small hysteresis loss and a low coercivity, in comparison to a fixed magnetic layer structure. In the context of various embodiments, a free magnetic layer structure may also be referred to as a “soft layer”, a “soft magnetic layer” or a “ferromagnetic soft layer”. In the context of various embodiments, the free magnetic layer structure may act as a storage layer.

In the context of various embodiments, the term “fixed magnetic layer structure” may mean a magnetic layer structure having a fixed magnetization orientation. The fixed magnetic layer structure may include a hard ferromagnetic material or a soft ferromagnetic material. The ferromagnetic material of the fixed magnetic layer structure may be resistant to magnetization and demagnetization (i.e. not easily magnetized and demagnetized), and may have a high hysteresis loss and a high coercivity as its magnetization is pinned. For example, each ferromagnetic layer 206, 208, 210 may have a hard ferromagnetic material or a soft ferromagnetic material, where the respective magnetizations of the ferromagnetic layer 206, 208, 210 are pinned by the exchange field in the synthetic antiferromagnetic layer structure 204.

In the context of various embodiments, the magnetoresistive device 200 may be a giant magnetoresistive (GMR) device or a tunnel magnetoresistive (TMR) device.

In the context of various embodiments, the magnetoresistive device 200 may be employed in a magnetoresistive random-access memory (MRAM) or a read/write head.

In various embodiments, an effective magnetic thickness (or magnetic moment) of the synthetic antiferromagnetic layer structure 204 may be at least substantially zero. This may mean that a sum of the respective magnetic thicknesses of the three ferromagnetic layers 206, 208, 210 may be at least substantially zero. In other words, the vector sum of the respective magnetic moments in the synthetic antiferromagnetic layer structure 204 may approach zero or may be at least close to zero. Therefore, in various embodiments, the vector sum of the respective magnetic moments of the three ferromagnetic layers 206, 208, 210 may be designed to be close to zero, so as to maintain pinning stability of the synthetic antiferromagnetic layer structure 204 (e.g. to provide a high exchange coupling field, Hₑₓ).

In the context of various embodiments, the terms “magnetic thickness” or “magnetic moment” with respect to a ferromagnetic layer may mean a parameter equivalent to the product of the magnetization (Mᵣ) of the ferromagnetic layer, and the thickness (t) of the ferromagnetic layer, i.e. magnetic thickness or magnetic moment=(Mᵣt). In various embodiments, for the synthetic antiferromagnetic layer structure 204, (Mᵣt)effective 0. This may help to improve the pinning stability of the synthetic antiferromagnetic layer structure 204.

In various embodiments, the ferromagnetic layer 208 sandwiched between the ferromagnetic layers 206, 210, may have a magnetic thickness that is at least substantially equal to a sum of the respective magnetic thicknesses of the ferromagnetic layers 206, 210. This may mean that (Mᵣt)_{FM 208}≈(Mᵣt)_{FM 206}+(Mᵣt)_{FM 210}.

In various embodiments, the ferromagnetic layer 206 that is arranged proximal to the free magnetic layer structure 202 may have a magnetic thickness that is smaller than the respective magnetic thicknesses of the other ferromagnetic layers 208, 210. This may help to reduce the offset field on the free magnetic layer structure 202 generated by the synthetic antiferromagnetic layer structure 204.

In various embodiments, the synthetic antiferromagnetic layer structure 204 may further include at least two antiferromagnetic coupling (AFC) layers, wherein a respective antiferromagnetic coupling layer of the at least two antiferromagnetic coupling layers may be arranged between respective adjacent ferromagnetic layers of the at least three ferromagnetic layers 206, 208, 210. This may mean that the synthetic antiferromagnetic layer structure 204 may have alternating layers of a ferromagnetic (FM) layer and an antiferromagnetic coupling (AFC) layer. Therefore, the synthetic antiferromagnetic layer structure 204 may have a multilayer arrangement having at least three ferromagnetic layers 206, 208, 210 and at least two antiferromagnetic coupling layers.

In various embodiments, at least one of the two antiferromagnetic coupling layers may be a metal spacer layer, for example a conductive and non-magnetic separating layer. The metal spacer layer may include ruthenium (Ru), tantalum (Ta), copper (Cu), silver (Ag), gold (Au), chromium (Cr), iridium (Ir) or any other metallic non-magnetic element or its alloy. At least one of the two antiferromagnetic coupling layers may have a thickness of between about 0.5 nm and about 2 nm, between about 0.5 nm and about 1 nm, or between about 1 nm and about 2 nm. As a non-limiting example, where the metal spacer layer includes ruthenium (Ru), the thickness may be about 0.8 nm.

The magnetoresistive device 200 may further include an antiferromagnetic (AFM) layer configured to pin the synthetic antiferromagnetic layer structure 204. The antiferromagnetic layer may be arranged adjacent to the synthetic antiferromagnetic layer structure 204. The synthetic antiferromagnetic layer structure 204 may be in contact with the antiferromagnetic layer. In various embodiments, the respective magnetization orientations of the three ferromagnetic layers 206, 208, 210 may be determined (e.g. fixed or pinned) by the antiferromagnetic layer.

The magnetoresistive device 200 may further include a spacer layer (SL) between the free magnetic layer structure 202 and the synthetic antiferromagnetic layer structure 204. The spacer layer may include a material selected from the group consisting of a conductive and non-magnetic material, a non-conductive and non-magnetic material, and an insulator material.

In various embodiments, the spacer layer may include a non-conductive and non-magnetic material, or an insulator material, for example including but not limited to any one of or any combination of magnesium oxide (MgO), alumina (AlOₓ), spinel (e.g. MgAl₂Oₓ) and titanium oxide (TiOₓ). By arranging a non-conductive and non-magnetic material or insulator as the spacer layer between the free magnetic layer structure 202 and the synthetic antiferromagnetic layer structure 204, the magnetoresistive device 200 may be configured as a tunnel magnetoresistive (TMR) device. The spacer layer including a non-conductive and non-magnetic material may have a thickness in a range of between about 0.3 nm and about 2.0 nm, e.g. between about 0.3 nm and about 1.5 nm, between about 0.3 nm and about 0.8 nm, between about 0.8 nm and about 2.0 nm, between about 0.8 nm and about 1.5 nm or between about 0.6 nm and about 1.2 nm.

In various embodiments, the spacer layer may include a conductive and non-magnetic material, for example including but not limited to any one of or any combination of copper (Cu), silver (Ag), gold (Au), tantalum (Ta), chromium (Cr), palladium (Pd), platinum (Pt), iridium (Ir), rhodium (Rh) or ruthenium (Ru). By arranging a conductive and non-magnetic material as the spacer layer between the free magnetic layer structure 202 and the synthetic antiferromagnetic layer structure 204, the magnetoresistive device 200 may be configured as a giant magnetoresistive (GMR) device. The spacer layer including a conductive and non-magnetic material may have a thickness of between about 1 nm and about 5 nm, e.g. between about 1 nm and about 3 nm, between about 1 nm and about 1.5 nm, between about 1.5 nm and about 5 nm, or between about 3 nm and about 5 nm, e.g. about 3 nm.

The magnetoresistive device 200 may further include a cancellation layer structure (or a field cancellation layer (FCL)) configured to provide a field to compensate for a field originating from the synthetic antiferromagnetic layer structure 204. In other words, the cancellation layer may generate a compensating or offsetting field to offset the field (e.g. stray field) generated by the synthetic antiferromagnetic layer structure 204. As a result, any field from the synthetic antiferromagnetic layer structure 204 acting on the free magnetic layer structure 202 may be minimised or removed. In various embodiments, the respective fields generated by the cancellation layer structure and the synthetic antiferromagnetic layer structure 204 may at least substantially cancel each other.

In various embodiments, the cancellation layer structure may be a ferromagnetic layer having a predetermined effective moment (or total moment) selected to fully compensate, or at least counteract, the effective field from the three ferromagnetic layers 206, 208, 210 of the synthetic antiferromagnetic layer structure 204.

In various embodiments, the cancellation layer structure may be arranged adjacent to the free magnetic layer structure 202. In various embodiments, the synthetic antiferromagnetic layer structure 204 and the cancellation layer structure may be arranged on opposite sides of the free magnetic layer structure 202.

In various embodiments, a magnetization orientation of the cancellation layer structure may be oriented anti-parallel to the magnetization orientation of the ferromagnetic layer 206 that is arranged proximal to the free magnetic layer structure 202.

The magnetoresistive device 200 may further include a non-magnetic spacer layer between the cancellation layer structure and the free magnetic layer structure 202. The non-magnetic spacer layer may include but not limited to one of or any combination of copper (Cu), silver (Ag), gold (Au), tantalum (Ta), chromium (Cr), palladium (Pd), platinum (Pt), iridium (Ir), rhodium (Rh) or ruthenium (Ru). In embodiments where the magnetoresistive device 200 is a TMR device, the non-magnetic spacer layer may include magnesium oxide (MgO), spinel (MgAl₂O) and aluminium oxide (AlO). The non-magnetic spacer layer may have a thickness in a range of between about 0.3 nm and about 10 nm, for example between about 0.3 nm and about 5 nm, between about 0.3 nm and about 2 nm, between about 2 nm and about 10 nm, or between about 5 nm and about 8 nm. In various embodiments, the strength of the field generated by the cancellation layer structure may be adjusted by controlling the distance between the cancellation layer structure and the free magnetic layer structure 202 (e.g. by adjusting the thickness of the non-magnetic spacer layer) and/or controlling the magnetization or coercivity of the cancellation layer structure. In various embodiments, the coercivity of the cancellation layer structure may be determined by the material(s) and/or layer arrangement of the cancellation layer structure.

In various embodiments, the cancellation layer structure may include a single layer, a bilayer structure or a multilayer structure (e.g. a multilayer structure of a plurality of the bilayer structures).

In various embodiments, the cancellation layer structure may include a synthetic antiferromagnetic layer structure, the synthetic antifferomagnetic layer including at least two antiferromagnetically coupled ferromagnetic layers. At least one antiferromagnetic coupling layer may be provided, where a respective antiferromagnetic coupling layer may be arranged in between adjacent antiferromagnetically coupled ferromagnetic layers. An antiferromagnetic layer may be arranged adjacent to the cancellation layer structure, for pinning the synthetic antiferromagnetic layer structure of the cancellation layer structure.

The magnetoresistive device 200 may further include a seed layer structure, wherein the free magnetic layer structure 202 and the synthetic antiferromagnetic layer structure 204 may be arranged over the seed layer structure. The seed layer structure may facilitate the formation or growth of the free magnetic layer structure 202 and/or the synthetic antiferromagnetic layer structure 204, for example so as to achieve suitable crystallographic and magnetic properties for the free magnetic layer structure 202 and/or the synthetic antiferromagnetic layer structure 204. The seed layer structure may include one or more layers including a material including but not limited to any one of or a combination of tantalum (Ta), palladium (Pd), platinum (Pt), ruthenium (Ru), chromium (Cr), nickel (Ni), tungsten (W), aluminum (Al), molybdenum (Mo), iron (Fe), titanium (Ti), silver (Ag), or gold (Au).

The magnetoresistive device 200 may further include a cap layer structure arranged over the free magnetic layer structure 202 and the synthetic antiferromagnetic layer structure 204. The cap layer structure may include one or more layers including a material including but not limited to any one of or a combination of tantalum (Ta), palladium (Pd), platinum (Pt), ruthenium (Ru), chromium (Cr), nickel (Ni), tungsten (W), aluminum (Al), molybdenum (Mo), titanium (Ti), silver (Ag), gold (Au), carbon (C), nitrogen (N) or hydrogen (H).

In various embodiments, the free magnetic layer structure 202 and the synthetic antiferromagnetic layer structure 204 may be arranged between the seed layer structure and the cap layer structure.

In the context of various embodiments, the cap layer structure and the seed layer structure may be configured or used as electrodes (e.g. top and bottom electrodes respectively) or separate metal electrodes may be formed or provided on the cap layer structure and the seed layer structure.

In the context of various embodiments, the free magnetic layer structure 202 may include a single layer or a bilayer structure or a multilayer structure of a plurality of the bilayer structures.

In the context of various embodiments, the ferromagnetic layer 206 that is arranged proximal to the free magnetic layer structure 202 may include a single layer or a bilayer structure or a multilayer structure of a plurality of the bilayer structures.

In the context of various embodiments, the “single layer” may mean a layer which, by itself, has the desired properties, while the composite structures (e.g. bilayer structure or multilayer structure) may mean a structure which, as a combination, has the desired properties.

In the context of various embodiments, each ferromagnetic layer 206, 208, 210 may have a thickness that is less than about 20 nm, for example between about 1 nm and about 20 nm, between about 1 nm and about 10 nm, between about 10 nm and about 20 nm, or between about 5 nm and about 15 nm.

In various embodiments, the thickness of the ferromagnetic layer 206 or the reference layer (RL) may be less than or equal to about 10 nm (i.e. ≦10 nm), for example in a range of between about 1 nm and about 10 nm, e.g. between about 1 nm and about 5 nm, between about 1 nm and about 2 nm, between about 5 nm and about 10 nm, or between about 2 nm and about 5 nm, e.g. about 2 nm.

In various embodiments, the thickness of the ferromagnetic layer 208 may be between about 3 nm and about 20 nm, e.g. between about 3 nm and about 10 nm, between about 3 nm and about 8 nm, between about 10 nm and about 20 nm, or between about 7 nm and about 15 nm, e.g. about 7 nm.

In various embodiments, the thickness of the ferromagnetic layer 210 may be between about 2 nm and about 19 nm, e.g. between about 2 nm and about 15 nm, between about 2 nm and about 8 nm, between about 8 nm and about 19 nm, or between about 5 nm and about 10 nm, or between about 5 nm and about 8 nm, e.g. about 5 nm.

In the context of various embodiments, the synthetic antiferromagnetic layer structure 204 may include one or more further ferromagnetic layers. Correspondingly, one or more further antiferromagnetic coupling layers may also be provided in the synthetic antiferromagnetic layer structure 204.

In the context of various embodiments, the free magnetic layer structure 202 may include a material including but not limited to cobalt (Co), iron (Fe), nickel (Ni), boron (B), nitrogen (N), or an alloy including at least one of cobalt (Co), iron (Fe), boron (B), or nickel (Ni), or a Heusler alloy such as Co₂MnSi, Co₂FeSi, Fe₂CrSi, Fe₂CrAl or their combination as: Co₂MnAlₓSi₁₋ₓ, Co₂FeAlₓSi₁₋ₓ, Fe₂CrₓCo₁₋ₓSi, where x=0 to 1; or Mn_{y}Ga, where y=1 to 3.

In the context of various embodiments, the free magnetic layer structure 202 may include cobalt-iron-boron (CoFeB), a (Co/Ni) bilayer structure, or a bilayer structure including a first layer of material selected from the group consisting of cobalt (Co), cobalt-iron (CoFe) and cobalt-iron-boron (CoFeB), and a second layer of material selected from the group consisting of palladium (Pd), platinum (Pt), iron-platinum (FePt) alloy, cobalt-platinum (CoPt) alloy, cobalt-iron (CoFe) and any combination thereof. For example, the free magnetic layer structure 202 may include a bilayer or a multilayer of (Co/X), (CoFe/X) or (CoFeB/X) where X is palladium (Pd), platinum (Pt), FePt alloy, MnGa, CoPt alloy, CoFe or any combination of these materials. Any combination of cobalt-iron-boron (CoFeB), (Co/Ni) multilayer, (Co/X) multilayer, (CoFe/X) multilayer and (CoFeB/X) multilayer may also be provided. As a non-limiting example, the free magnetic layer structure 202 may include (CoFe/Pd)₅, having 5 layers of CoFe arranged alternately with 5 layers of Pd, for example an arrangement of (CoFe/Pd/CoFe/Pd/CoFe/Pd/CoFe/Pd/CoFe/Pd). In embodiments with a multilayer structure, the number of repeats of bilayer structures may be more than or equal to 2, e.g. 2, 3, 4, 5 or any higher number.

In the context of various embodiments, the free magnetic layer structure 202 may have a thickness of between about 0.8 nm and about 10 nm, for example between about 0.8 nm and about 5 nm, between about 0.8 nm and about 2 nm, between about 2 nm and about 10 nm, between about 2 nm and about 5 nm, or between about 4 nm and about 6 nm.

In the context of various embodiments, the ferromagnetic layer 206 or the reference layer (RL) may include a material including but not limited to cobalt (Co), iron (Fe), nickel (Ni), boron (B), nitrogen (N), or an alloy including at least one of cobalt (Co), iron (Fe), boron (B), or nickel (Ni).

In the context of various embodiments, the ferromagnetic layer 206 or the reference layer (RL) may include cobalt-iron-boron (CoFeB), a (Co/Ni) bilayer structure, or a bilayer structure including a first layer of material selected from the group consisting of cobalt (Co), cobalt-iron (CoFe) and cobalt-iron-boron (CoFeB), and a second layer of material selected from the group consisting of palladium (Pd), platinum (Pt), iron-platinum (FePt) alloy, cobalt-platinum (CoPt) alloy, cobalt-iron (CoFe) and any combination thereof. For example, the ferromagnetic layer 206 or the reference layer (RL) may include a bilayer or a multilayer of (Co/X), (CoFe/X) or (CoFeB/X) where X is palladium (Pd), platinum (Pt), FePt alloy, CoPt alloy, CoFe or any combination of these materials. Any combination of cobalt-iron-boron (CoFeB), (Co/Ni) multilayer, (Co/X) multilayer, (CoFe/X) multilayer and (CoFeB/X) multilayer may also be provided. As a non-limiting example, the ferromagnetic layer 206 or the reference layer (RL) may include (CoFe/Pd)₅, of 5 layers of CoFe arranged alternately with 5 layers of Pd, for example an arrangement of (CoFe/Pd/CoFe/Pd/CoFe/Pd/CoFe/Pd/CoFe/Pd). In embodiments with a multilayer structure, the number of repeats of bilayer structures may be more than or equal to 2, e.g. 2, 3, 4, 5 or any higher number.

In the context of various embodiments, each of the ferromagnetic layers 208, 210 may be a pinned layer (PL) and may include cobalt (Co).

In the context of various embodiments, an antiferomagnetic (AFM) layer may include a material including X-manganese or X-Y-manganese, wherein each of X and Y includes but not limited to platinum (Pt), palladium (Pd), iridium (Ir), rhodium (Rh), ruthenium (Ru) or iron (Fe).

In the context of various embodiments, an antiferromagnetic (AFM) layer may have a thickness of between about 4 nm and about 30 nm, for example between about 4 nm and about 20 nm, between about 4 nm and about 10 nm, between about 10 nm and about 30 nm, between about 10 nm and about 20 nm or between about 8 nm and about 15 nm.

In the context of various embodiments, the magnetoresistive device 200 may have in-plane anisotropy. This may mean that the magnetization orientation of a ferromagnetic layer may be parallel to the plane of a major surface of the ferromagnetic layer. This may mean that the magnetization orientation of the ferromagnetic layer may be at least substantially perpendicular to a thickness direction of the ferromagnetic layer.

In the context of various embodiments, the magnetoresistive device 200 may have perpendicular anisotropy. This may mean that the magnetization orientation of a ferromagnetic layer may be perpendicular to the plane of a major surface of the ferromagnetic layer. This may mean that the magnetization orientation of the ferromagnetic layer may be at least substantially parallel to a thickness direction of the ferromagnetic layer.

In the context of various embodiments, the term “spacer layer” may be interchangeably used with the term “separation layer”.

In the context of various embodiments, the resistance state of the magnetoresistive device 200 may change as a result of a change in its resistivity.

In the context of various embodiments, the free magnetic layer structure 202 and the synthetic antiferromagnetic layer structure 204 may be part of or form part of a magnetic junction of the magnetoresistive device 200. Other layers as described herein may also be part of or form part of the magnetic junction. As a non-limiting example, the magnetic junction may be a magnetic tunnel junction (MTJ), for example for a tunnel magnetoresistive (TMR) device.

In the context of various embodiments, the magnetoresistive device 200 may be or may form part of a memory device, e.g. a magnetoresistive random access memory (MRAM), for example an MRAM with perpendicular anisotropy or in-plane anisotropy.

In the context of various embodiments, the term “adjacent” as applied to two layers may include an arrangement where the two layers are in contact with each other or an arrangement where the two layers are separated by an intermediate layer, e.g. a spacer layer.

FIG. 2B shows a flow chart 220 illustrating a method for manufacturing a magnetoresistive device, according to various embodiments.

At 222, a free magnetic layer structure having a variable magnetization orientation is formed.

At 224, a synthetic antiferromagnetic layer structure is formed, the synthetic antiferromagnetic layer structure including at least three ferromagnetic layers arranged one over the other and antiferromagnetically coupled, each ferromagnetic layer having a fixed magnetization orientation, wherein the free magnetic layer structure and the synthetic antiferromagnetic layer structure are arranged one over the other.

In various embodiments, an effective magnetic thickness of the synthetic antiferromagnetic layer structure may be at least substantially zero.

The method may further include forming a cancellation layer structure, the cancellation layer structure configured to provide a field for compensating a field originating from the synthetic antiferromagnetic layer structure.

In various embodiments, in order to overcome or at least address the above-mentioned problems related to conventional devices, various embodiments may provide a synthetic antiferromagnetic (SAF) multilayer structure. Instead of two ferromagnetic (FM) layers (e.g. a reference layer (RL) and a pinned layer (PL)) and one antiferromagnetic coupling (AFC) layer in a simple (conventional) SAF, the SAF multilayer of various embodiments may include many FM layers (e.g. more than two FM layers, e.g. at least three FM layers) and many AFC layers (e.g. more than one AFC layer, e.g. at least two AFC layers). The multilayer SAF structure of various embodiments may reduce the stray field on the free layer.

FIG. 3 shows a schematic diagram of a magnetoresistive device 300, according to various embodiments. The magnetoresistive device 300 may be a giant magnetoresistive (GMR) device or a tunnel magnetoresistive (TMR) device. The magnetoresistive device 300 may have a stack structure.

The magnetoresistive device 300 may include a seed layer (or seed layer structure) 304, an antiferromagnetic (AFM) pinning layer 306, a pinned layer (PLa) 308a, an antiferromagnetic coupling layer (AFCa) 310a, a pinned layer (PLb) 308b, an antiferromagnetic coupling layer (AFCb) 310b, a reference layer (RL) 312, a spacer layer (SL) 314, a free layer (FL) (or free magnetic layer structure) 316, and a cap layer (or cap layer structure) 318. Adjacent layers may be in direct contact with each other. As may be seen in FIG. 3, the number of PL is more than one (e.g. PLa 308a and PLb 308b) and the number of AFC layer is more than one (e.g. AFCa 310a and AFCb 310b).

The pinned layer (PLa) 308a, the antiferromagnetic coupling layer (AFCa) 310a, the pinned layer (PLb) 308b, the antiferromagnetic coupling layer (AFCb) 310b and the reference layer (RL) 312 form a synthetic antiferromagnetic (SAF) structure 302. Therefore, the SAF structure 302 includes three ferromagnetic (FM) layers (PLa 308a, PLb 308b, and RL 312). The magnetization orientation of RL 312 may be pinned by the SAF structure 302.

As a non-limiting example as shown in FIG. 3, the SAF structure 302 is a multilayer structure including three ferromagnetic (FM) layers in the form of PLa 308a, PLb 308b, and RL 312, and two antiferromagnetic coupling (AFC) layers in the form of AFCa 310a and AFCb 310b. PLa 308a, PLb 308b, and RL 312 of the SAF structure 302 are antiferromagnetically coupled. This may mean that the respective magnetization orientations of PLa 308a and PLb 308b may be anti-parallel (in opposite directions) relative to each other (i.e. antiferromagnetically coupled), while the respective magnetization orientations of PLb 308b and RL 312 may be anti-aligned or anti-parallel relative to each other (i.e. antiferromagnetically coupled). This may also mean that the respective magnetization orientations of PLa 308a and RL 312 may be aligned parallel (in the same direction) relative to each other. The SAF structure 302 may be pinned by AFM 306. This may mean that the magnetization orientation of RL 312 may be determined by AFM 306.

As an example, where the magnetoresistive device 300 is an in-plane magnetization device, the magnetization orientation of PLa 308a may point towards the right, as illustrated by the arrow 320a, the magnetization orientation of PLb 308b may point towards the left, as illustrated by the arrow 320b, while the magnetization orientation of RL 312 may point towards the right, as illustrated by the arrow 320c. It should be appreciated that the respective magnetization orientations of PLa 308a, PLb 308b and RL 312 may instead point in the reverse direction. The magnetization orientation of FL 316, as illustrated by the arrow 320d, may be switched between two directions. As shown in FIG. 3, the magnetization orientation 320d may be in any one of two directions, either pointing towards the right or towards the left.

As a further example, where the magnetoresistive device 300 is a perpendicular magnetization device, the magnetization orientation of PLa 308a may point towards the top (upwardly), as illustrated by the arrow 322a, the magnetization orientation of PLb 208b may point towards the bottom (downwardly), as illustrated by the arrow 322b, while the magnetization orientation of RL 312 may point towards the top (upwardly), as illustrated by the arrow 322c. It should be appreciated that the respective magnetization orientations of PLa 308a, PLb 308b and RL 312 may instead point in the reverse direction. The magnetization orientation of FL 316, as illustrated by the arrow 322d, may be switched between two directions. As shown in FIG. 3, the magnetization orientation 322d may be in any one of two directions, either pointing upwardly or downwardly.

In various embodiments where SL 314 is a conductive and non-magnetic material, for example including but not limited to any one of or any combination of copper (Cu), silver (Ag), gold (Au), tantalum (Ta), chromium (Cr), palladium (Pd), platinum (Pt), iridium (Ir), rhodium (Rh) or ruthenium (Ru), the magnetoresistive device 300 may be a GMR device.

In various embodiments where SL 314 is a non-conductive and non-magnetic material or an insulator material, for example including but not limited to any one of or any combination of magnesium oxide (MgO), spinel (e.g. MgAl₂Ox), alumina (AlOₓ), and titanium oxide (TiOₓ), the magnetoresistive device 300 may be a TMR device.

In various embodiments, for the SAF multilayer structure 302, the vector sum of the magnetization of each FM layer (PLa 308a, PLb 308b, RL 312) may be designed to be close to zero to maintain pinning field, e.g. to provide a high exchange coupling field, Hₑₓ. In other words, the design requirement may be provided to minimize the effective magnetic thickness of the SAF multilayer structure 302. For the SAF multilayer 302 shown in FIG. 3, Hₑₓ may be determined as follows:

$${H}_{ex} ∝ \frac{J}{{( {M}_{r} t )}_{Pb} - {( {M}_{r} t )}_{Pa} - {( {M}_{r} t )}_{R}} , \qquad ( Equation 2 )$$

where J is the exchange strength between PLa 308a and AFM layer 306, Mᵣ is the remanent magnetization, t is the thickness, (Mᵣt)_{Pb} is the magnetic thickness of PLb 308b, (Mᵣt)_{Pa} is the magnetic thickness of PLa 308a, and (Mᵣt)_{R} is the magnetic thickness of RL 312.

In order to provide a high Hₑₓ, it is desired to have (Mᵣt)_{Pb}≈(Mᵣt)_{Pa}+(Mᵣt)_{R}, as may be seen from Equation 2. Further, in order to reduce the offset field from the SAF multilayer structure 302, for example onto FL 316, a small (Mᵣt)_{R} and a large (Mᵣt)_{Pa} may be provided so that the spatial loss of the stray field due to the individual magnetic layers PLb 308b and RL 312 may be compensated by the larger moment of PLa 308a.

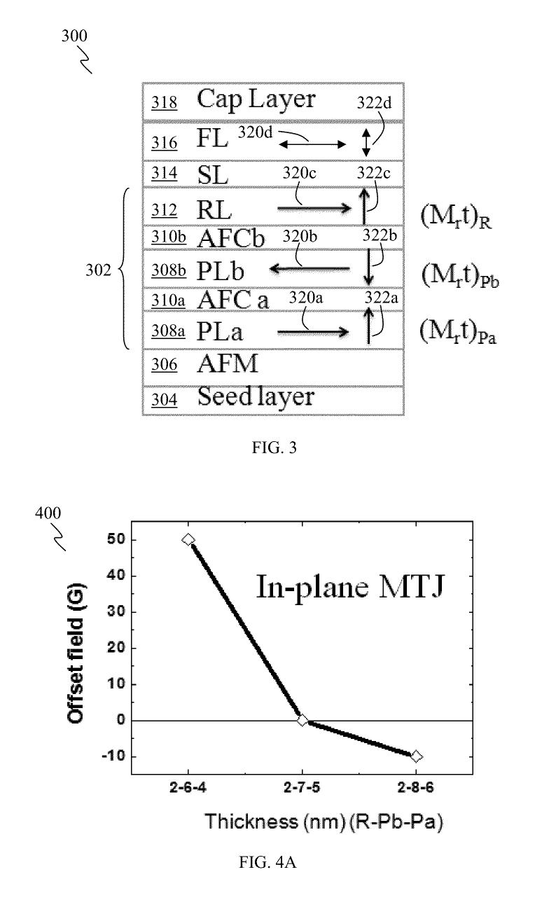

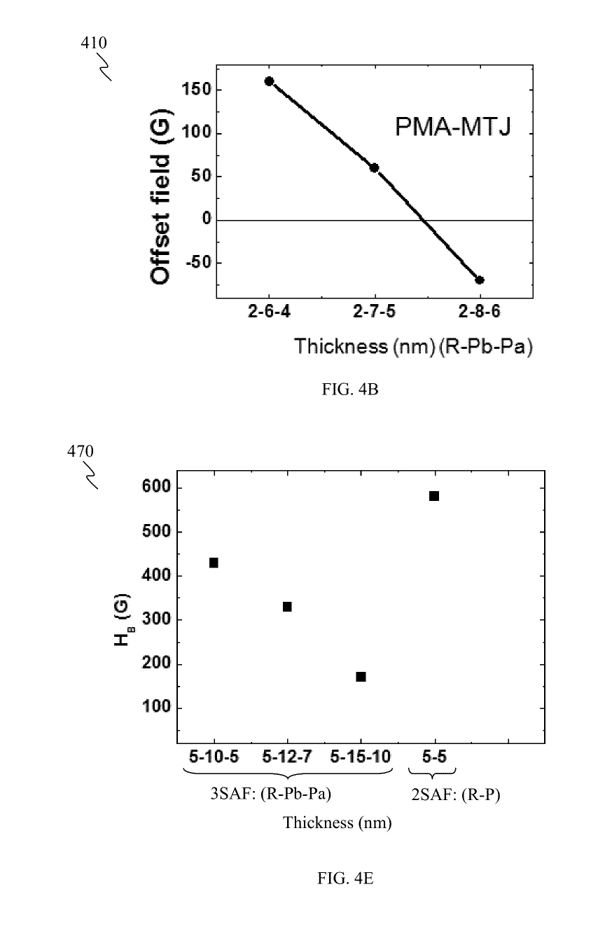

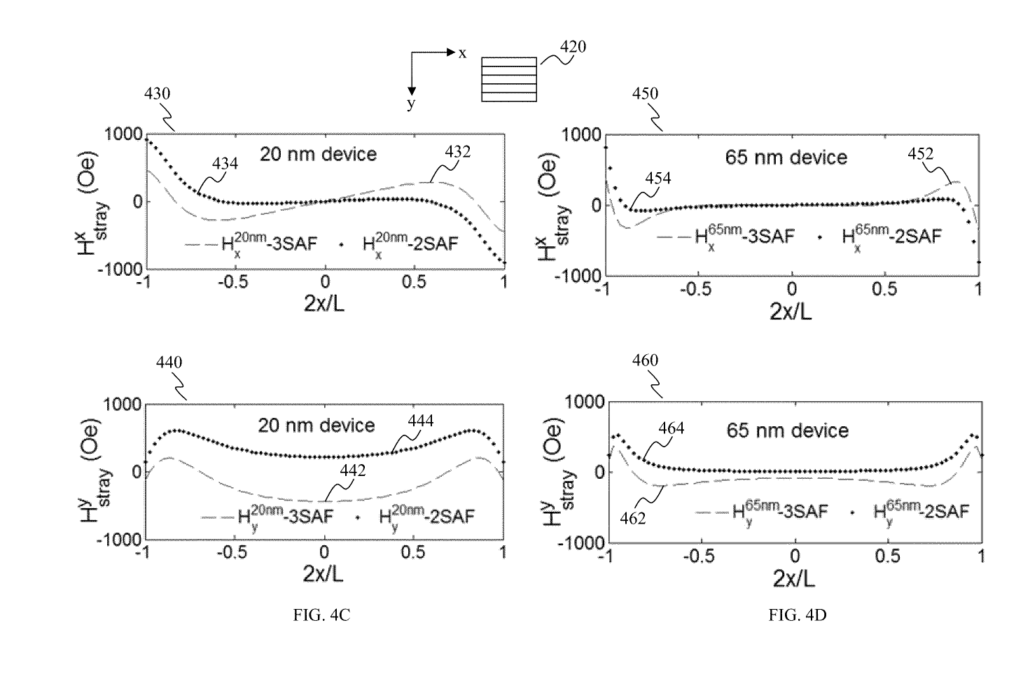

FIG. 4A shows a plot 400 of simulated offset field for an in-plane magnetic anisotropy device (e.g. an in-plane magnetic tunnel junction (MTJ) device), for different thickness combinations of the synthetic antiferromagnetic (SAF) multilayer, according to various embodiments. FIG. 4B shows a plot 410 of simulated offset fields for a perpendicular magnetic anisotropy device (e.g. a perpendicular magnetic anisotropy (PMA) magnetic tunnel junction (MTJ) device), for different thickness combinations of the synthetic antiferromagnetic (SAF) multilayer, according to various embodiments. In FIGS. 4A and 4B, the values indicated for the x-axis represent the respective thicknesses of the ferromagnetic layers based on the SAF structure 302 of the embodiment of FIG. 3. The thicknesses are for the reference layer (RL) 312 and the two pinned layers, PLa 308a and PLb 308b, labelled as (R—Pb—Pa).

Based on the results shown in FIGS. 4A and 4B, micromagnetics simulations show that the bias field may be minimised while keeping the pinning stability with (Mᵣt)_{Pb}=(Mᵣt)_{Pa}+(Mᵣt)_{R}. As may be observed from FIG. 4A, at the thickness of about 2 nm, about 7 nm and about 5 nm respectively for RL 312, PLb 308b and PLa 308a, the offset field may be effectively removed in the in-plane MTJ device (size approximately 20 nm×20 nm). In other words, the bias field close to zero may be obtained with t_{R}=2 nm, t_{Pb}=7 nm and t_{Pa}=5 nm.

For the PMA-MTJ device (size approximately 20 nm×20 nm), as may be observed in FIG. 4B, in order to fully or at least substantially remove the bias field, the thickness of the middle layer (PLb 308b) should be slightly increased as compared to that for the in-plane MTJ device, e.g. a thickness of approximately 7.5 nm for PLb 308b.

FIGS. 4C and 4D show respective plots of stray fields at the middle of a free layer of a perpendicular magnetic anisotropy device, for different SAF structures for a 20 nm (e.g. diameter) device and a 65 nm (e.g. diameter) device respectively, according to various embodiments. For illustration purposes, a schematic diagram of a magnetoresistive device 420 is shown, with the associated x-direction and y-direction with respect to the magnetoresistive device 420. The legends indicated as “2SAF” refers to a magnetoresistive device with a simple SAF structure having two FM layers where each FM layer is 2 nm thick, while “3SAF” refers to a magnetoresistive device with a SAF structure of various embodiments, having three FM layers where, based on the SAF structure 302 (FIG. 3), the thicknesses for RL 312, PLb 308b and PLa 308a are about 2 nm, about 7 nm and about 5 nm, respectively.

FIG. 4C shows a plot 430 of H^{x}_{stray}, showing result 432 for a 20 nm device with a 3SAF structure and result 434 for a 20 nm device with a 2SAF structure. FIG. 4C also shows a plot 440 of H^{y}_{stray}, showing result 442 for a 20 nm device with a 3SAF structure and result 444 for a 20 nm device with a 2SAF structure. In plot 430, the notations “H^{x}” for the y-axis and “Hₓ” for the legend refer to the same parameter, being the stray field along the x-direction, while in plot 440, the notations “H^{y}” for the y-axis and “H_{y}” for the legend refer to the same parameter, being the stray field along the y-direction.

FIG. 4D shows a plot 450 of H^{x}_{stray}, showing result 452 for a 65 nm device with a 3SAF structure and result 454 for a 65 nm device with a 2SAF structure. FIG. 4D also shows a plot 460 of H^{y}_{stray}, showing result 462 for a 65 nm device with a 3 SAF structure and result 464 for a 65 nm device with a 2SAF structure. In plot 450, the notations “H^{x}” for the y-axis and “Hₓ” for the legend refer to the same parameter, being the stray field along the x-direction, while in plot 460, the notations “H^{y}” for the y-axis and “H_{y}” for the legend refer to the same parameter, being the stray field along the y-direction.

In plots 430 and 440 of FIG. 4C and plots 450 and 460 of FIG. 4D, the term “2x/L” for the x-axis refers to a normalised parameter where its range is between −1 and 1, where x refers to the spatial position along the x-direction, with an origin at the center of the device 420, while L is the device size or length.

Further, it is realized that the offset field may be removed only in a certain thickness range for the reference layer 312. FIG. 4E shows a plot 470 of simulated offset field for a perpendicular magnetic anisotropy device (e.g. PMA-MTJ device) with a cell diameter of about 65 nm, for different thickness combinations of the synthetic antiferromagnetic (SAF) multilayer, according to various embodiments. Plot 470 shows the results for a 3SAF structure having RL 312 with a thickness of about 5 nm and different thickness for PLb 308b and PLa 308a. For comparison, plot 470 also shows the result for a conventional SAF structure (2SAF), where the reference layer and the pinned layer have the same thickness of 5 nm. The results in FIG. 4E, as compared to the results in FIG. 4B, show that as the thickness of RL 312 is increased, thicker PLb 308b and PLa 308a may be required to minimise or remove the bias field or offset field.

When the thickness of the reference layer 312 is large, e.g. more than 10 nm, the field from PLb 308b may not be large enough to compensate the stray field of the reference layer 312 due to the large spatial loss of the field from PLb 308b. For example, when the reference layer (e.g. CoFeB layer) is very thick, there may be challenges in reducing the offset field to zero for a PMA-MTJ due to a large spatial loss. Accordingly, a thickness of 10 nm or less (i.e. ≦10 nm) may be provided for the reference layer 312 in various embodiments.

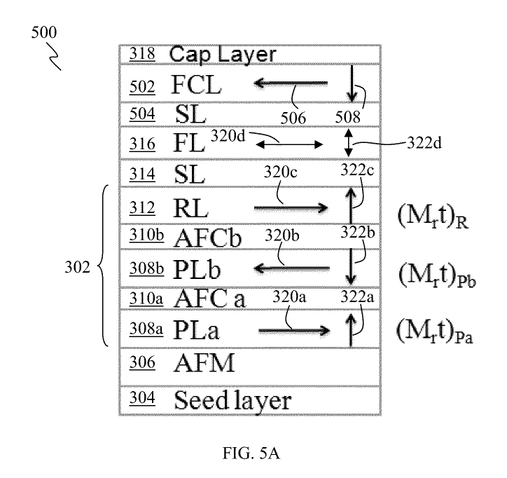

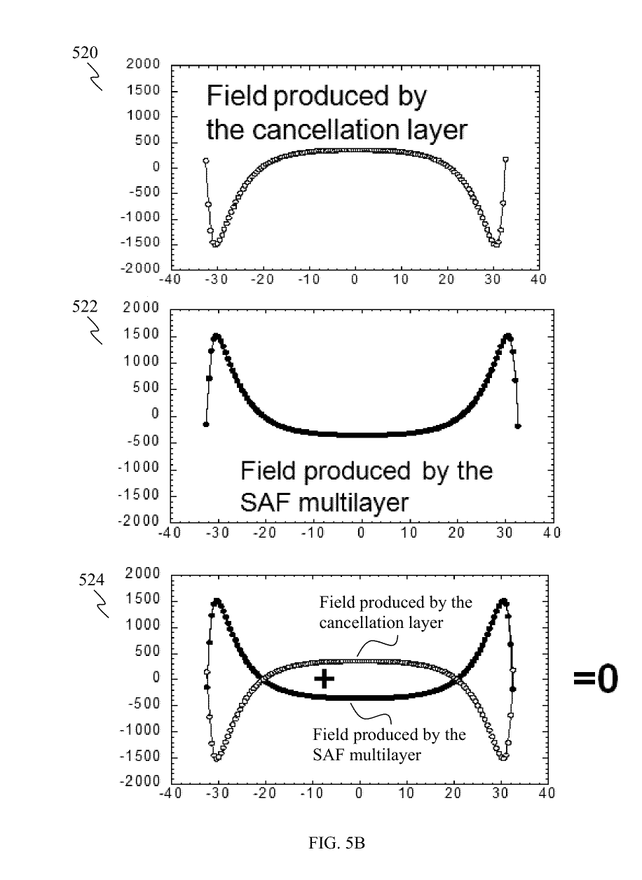

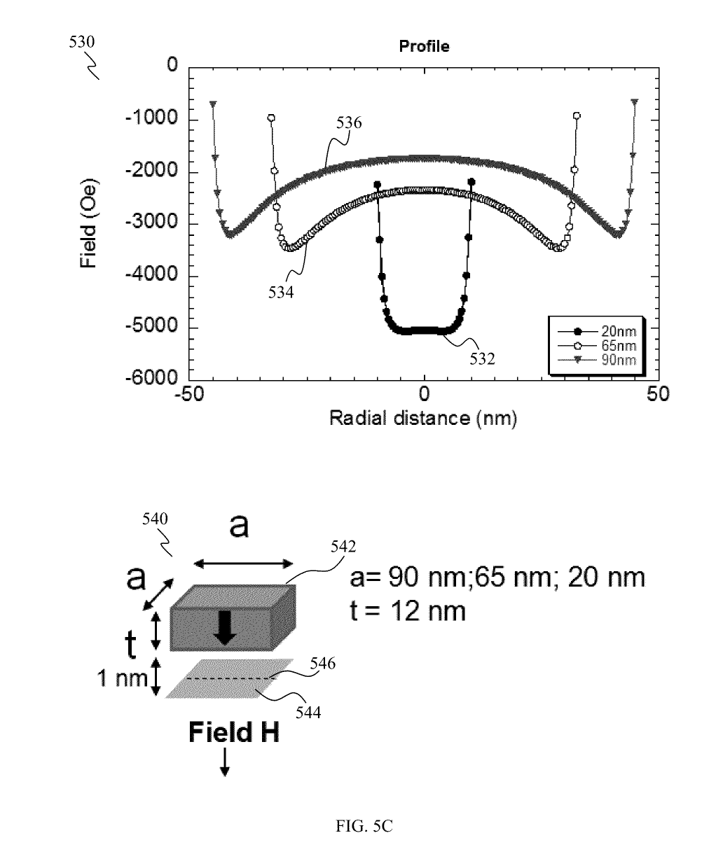

In order to increase the cancellation field, an additional cancellation layer may be arranged adjacent to the free layer (FL), separated by a non-magnetic space layer, as shown in FIG. 5A for a magnetoresistive device 500. Layers that are present in the magnetoresistive device 500 that are similarly present in the magnetoresistive device 300 (FIG. 3) are denoted by the same reference numerals, and the corresponding descriptions are omitted here. The magnetoresistive device 500 further includes a cancellation layer or field cancellation layer (FCL) 502 arranged adjacent to FL 316. A non-magnetic spacer layer (SL) 504 may be arranged between FCL 502 and FL 316. FCL 502 and the SAF structure 302 may be arranged on opposite sides of FL 316.

FCL 502 may be a ferromagnetic (FM) layer with its total moment predetermined or properly selected to partially or fully compensate the additional stray field from RL 312, PLb 308b and PLa 308a. In various embodiments, the magnetoresistive device 500 combines the SAF multilayer structure 302 with the cancellation layer 502 to cancel or at least minimise the offset field in any thickness range.

The magnetization orientation of FCL 502 and the magnetization orientation of RL 312 may be anti-parallel, in other words, oriented in opposite directions, to further reduce the field from the SAF structure 302. For example, based on the illustration in FIG. 5A, in embodiments where the magnetoresistive device 500 is an in-plane magnetization device, the magnetization orientation of FCL 502 may point towards the left, as illustrated by the arrow 506. However, it should be appreciated that the magnetization orientation 506 of FCL 502 may be reversed, depending on the magnetization orientation 320c of RL 312. In embodiments where the magnetoresistive device 500 is a perpendicular magnetization device, the magnetization orientation of FCL 502 may point towards the bottom (downwardly), as illustrated by the arrow 508.

However, it should be appreciated that the magnetization orientation 508 of FCL 502 may be reversed, depending on the magnetization orientation 322c of RL 312.

In various embodiments, the field strength from or of FCL 502 may be adjusted by controlling its distance from FL 316, for example by changing the thickness of SL 504, and/or controlling the FCL magnetization. The coercivity of FCL 502 may be adjusted by using a magnetic multilayer composition and repeats of the magnetic multilayer composition.

FIG. 5B illustrates the effect of a field produced by a cancellation layer on a stray field produced by a SAF multilayer structure, according to various embodiments. FIG. 5B shows a plot 520 illustrating the field produced by FCL 502, a plot 522 illustrating the field (stray field) produced by the SAF multilayer structure 302 and plot 524 illustrating the cancellation effect of the field generated by FCL 502 on the stray field originating from the SAF multilayer structure 302. As illustrated in plot 524, the stray field may be fully compensated by the field from the FCL 502, thereby producing a zero net field.

FIG. 5C shows a plot 530 of stray field of a magnetoresistive device 540 without a cancellation layer, according to various embodiments. For clarity purposes, only the ferromagnetic layer (e.g. a reference layer (RL)) 542 having a magnetization orientation in the downward direction is shown in FIG. 5C. The layer 542, and the magnetoresistive device 540, have a square cross-section with dimensions “a”, and a thickness, t, of about 12 nm. The gray area 544 refers to the plane where a free magnetic layer (FL) may be positioned. Therefore, the gap of 1 nm between the layer 542 and the gray area 544 may refer to the thickness of a spacer layer arranged in between the layer 542 and the free layer. Further, the gray area 544 is the physical plane used for the field calculation for the results obtained in plot 530. The dotted line 546 is used for the calculation of the radial distance for the results obtained in plot 530. A value of “0” for that radial distance refers to the center of the dotted line 546.

Plot 530 shows result 532 for a magnetoresistive device 540 with the dimension, a=20 nm, result 534 for a magnetoresistive device 540 with the dimension, a=65 nm, and result 536 for a magnetoresistive device 540 with the dimension, a=90 nm. As may be observed, there may be a large stray field for a magnetoresistive device without a cancellation layer.

It should be appreciated that while FIG. 5A illustrates that the cancellation layer 502 is arranged over the SAF multilayer structure 302 for a magnetoresistive device with a bottom spin valve, where the SAF multilayer structure 302 is arranged at the bottom, the respective positions of the SAF multilayer structure 302 and FCL 502 may be exchanged to provide a magnetoresistive device with a top spin valve.

As illustrated in FIGS. 3 and 5A, it should be appreciated that various embodiments may be suitable for both in-plane anisotropy devices and perpendicular anisotropy devices.

The initialization process or scheme for the magnetoresistive device of various embodiments will now be described by way of the following non-limiting examples. Based on the magnetoresistive device 500 having the SAF multilayer structure 302, with a perpendicular anisotropy, the pinning direction may be built up or produced during high temperature annealing via a high “pointing-up” magnetic field (i.e. an upward magnetic field). After cooling down to room temperature, the magnetization of the cancellation layer 502 may be initialized by applying a downward magnetic field. As the unidirectional easy axis corresponding to the SAF multilayer structure 302 has been set up during the earlier annealing process, the magnetization direction or orientation of the entire SAF multilayer structure 302 may not be changed after the initialization of FCL 502. It should be appreciated that the respective magnetic fields may be reversed. In the context of various embodiments, the term “easy axis” as applied to magnetism may mean an energetically favorable direction of spontaneous magnetization as a result of magnetic anisotropy. The magnetization orientation of a ferromganetic layer may be aligned along the easy axis.

In embodiments having an even number of FM layers (e.g. four, six, eight, etc.) in the SAF multilayer (e.g. similar to a single SAF which has even number (two) of FM layers), initialization of the cancellation layer may be done simultaneously during the annealing process as the pinning field direction is the same as the desired magnetization direction of the cancellation layer.

Different initilization schemes may be employed to provide a cancellation layer having an opposite polarity to the reference layer, as will be described below.

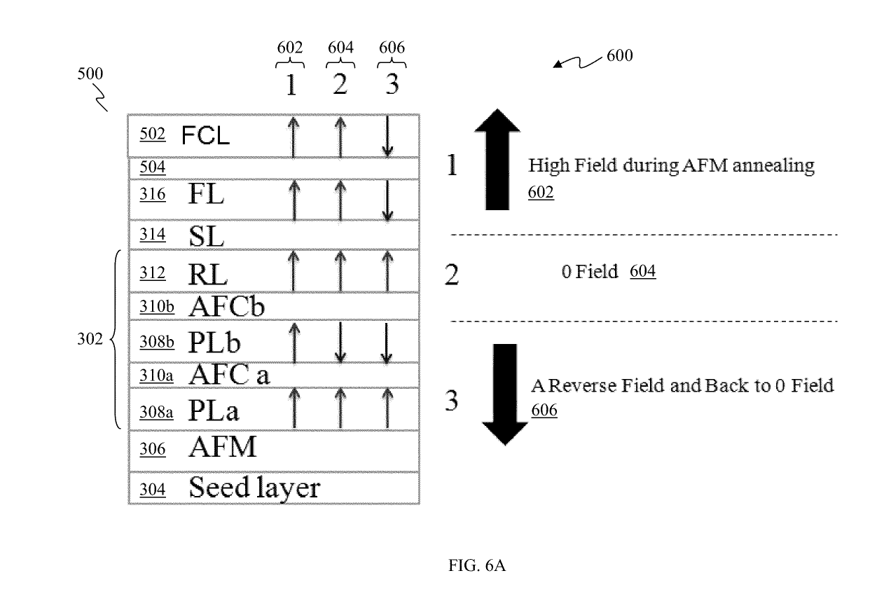

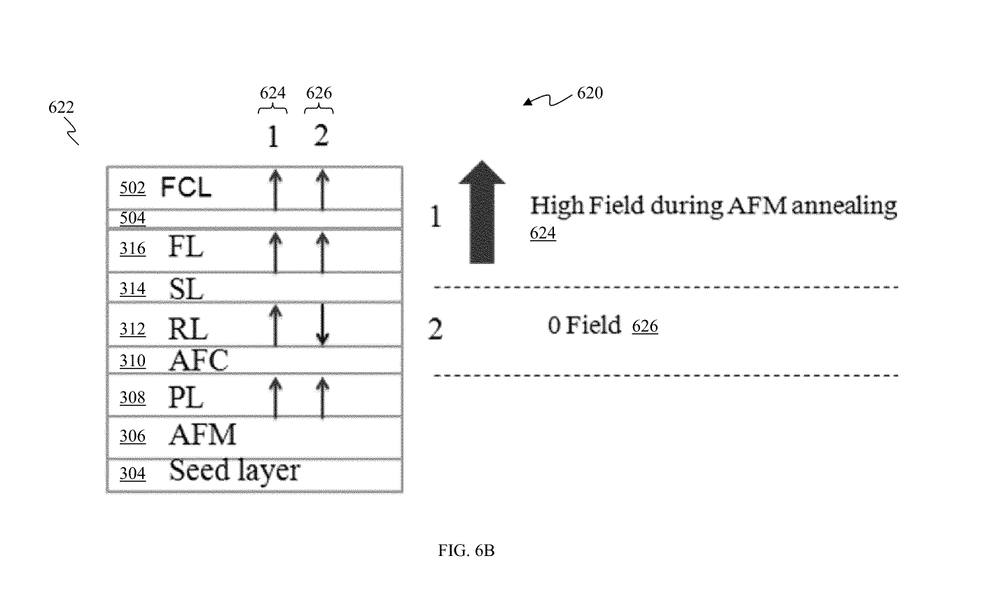

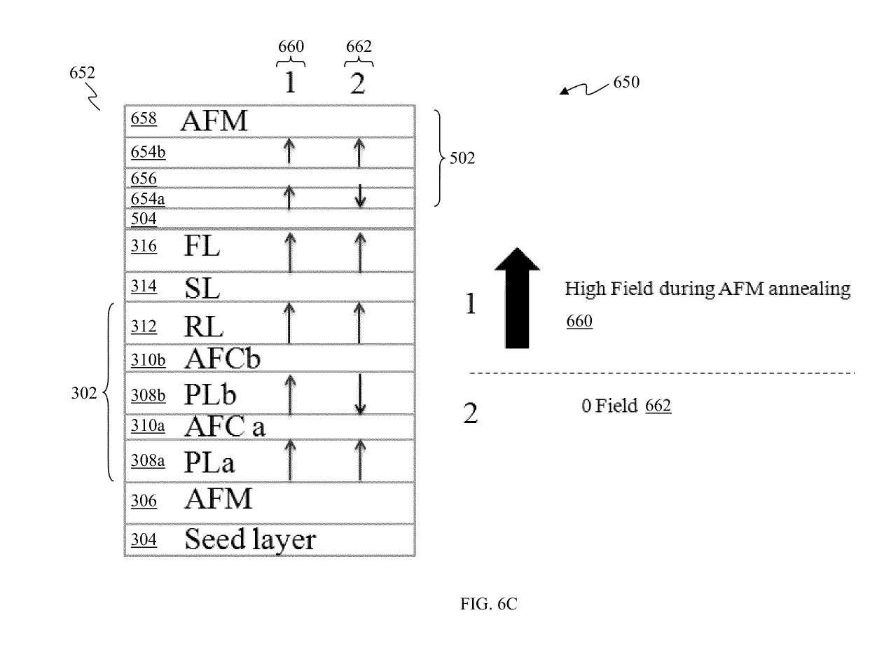

FIG. 6A shows an initialization scheme 600 for the magnetoresistive device 500 (FIG. 5A), according to various embodiments. In a first step indicated as 602, a high upward pointing magnetic field may be applied during AFM annealing, which may cause the respective magnetization orientations associated with FCL 502, FL 316, RL 312, PLb 308b and PLa 308a to point in the upwardly direction. Subsequently, in a step indicated as 604, the magnetic field is removed (i.e. no field is applied), which may cause the magnetization orientation of PLb 308b to switch to a downwardly direction. In a third step indicated as 606, a reverse field (downward pointing magnetic field) may be applied, causing the respective magnetization orientations of FCL 502 and FL 316 to switch to a downwardly direction. The reverse field may then be removed, and the respective magnetization orientations of FCL 502, FL 316 and PLb 308b may be maintained in a downwardly direction, while the respective magnetization orientations of RL 312 and PLa 308a may be maintained in an upwardly direction. Therefore, the respective orientations of FCL 502 and RL 312 may be in opposite directions.

FIG. 6B shows an initialization scheme (e.g. self-initialization scheme) 620 for a magnetoresistive device 500 having a SAF multilayer structure including an even number (higher than two) of FM layers, according to various embodiments. For ease of understanding, only two FM layers in the form of RL 312 and PL 308 are shown in FIG. 6B and the initialization scheme 620 will be described in terms of the two FM layers (RL 312 and PL 308) illustrated in FIG. 6B. In a first step indicated as 624, a high upward pointing magnetic field may be applied during AFM annealing, which may cause the respective magnetization orientations associated with FCL 502, FL 316, RL 312 and PL 308 to point in the upwardly direction. Subsequently, in a step indicated as 626, no field is applied, which may cause the magnetization orientation of RL 312 to switch to a downwardly direction. Therefore, the respective orientations of FCL 502 and RL 312 may be in opposite directions.

FIG. 6C shows an initialization scheme (e.g. self-initialization scheme) 650 for a magnetoresistive device 652, according to various embodiments. The magnetoresistive device 652 is similar to the magnetoresistive device 500 except that the cancellation layer, FCL, 502 for the magnetoresistive device 652 is a normal synthetic antiferromagnetic (SAF) structure. The SAF structure 502 includes two ferromagnetic (FM) layers 654a, 654b, separated by a spacer layer 656, and pinned by an antiferromagnetic (AFM) layer 658.

In a first step indicated as 660, a high upward pointing magnetic field may be applied during AFM annealing, which may cause the respective magnetization orientations associated with the two FM layers 654a, 654b of FCL 502, FL 316, RL 312, PLb 308b and PLa 308a to point in the upwardly direction. Subsequently, in a step indicated as 662, no field is applied, which may cause the respective magnetization orientations of PLb 308b and the FM layer 654a to switch to a downwardly direction. Therefore, the respective orientations of the FM layer 654a and RL 312 may be in opposite directions.

As described above, the synthetic antiferromagnetic (SAF) multilayer structure of various embodiments may include many FM layers (e.g. more than two FM layers) and many AFC layers (e.g. more than one AFC layer). As a non-limiting example, the SAF multilayer structure may include three FM layers, for example a reference layer (RL) and two pinned layers (PL) (e.g. PLa and PLb) that are antiferromagnetically coupled, and two AFC layers (e.g. AFCa and AFCb). In the SAF multilayer structure, pinning stability may be achieved by selecting the material and/or thickness of any one FM layer or each FM layer so that (Mᵣt)_{Pb}≈(Mᵣt)_{Pa}+(Mᵣt)_{R}. The offset field from the SAF multilayer may be reduced or removed by having a small (Mᵣt)_{R} and a large (Mᵣt)_{Pa} so that the spatial loss of the magnetic field may be compensated by the larger moment. In order to provide an additional cancellation field, an additional cancellation layer may be placed adjacent to the free layer, separated by a non-magnetic spacer layer. The cancellation layer may be a ferromagnetic (FM) layer with its total moment properly selected to partially or fully compensate the additional stray field from the three ferromagnetic layers of the SAF structure of various embodiments.

The pinning structure with a synthetic antiferromagnetic (SAF) multilayer structure of various embodiments may reduce the offset of a bias point without sacrificing the pinning stability for small magnetic tunnel junction (MTJ) devices (or tunnel magnetoresistive (TMR) devices) and giant magnetoresistive (GMR) devices. In addition, the bias field may further be compensated using a cancellation layer adjacent to the free layer. The initialization of the magnetization of the cancellation layer may be completed without affecting the pinning field.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

1. A magnetoresistive device comprising:
a free magnetic layer structure having a variable magnetization orientation; and
a synthetic antiferromagnetic layer structure comprising at least three ferromagnetic layers arranged one over the other and antiferromagnetically coupled, each ferromagnetic layer having a fixed magnetization orientation,
wherein the free magnetic layer structure and the synthetic antiferromagnetic layer structure are arranged one over the other.

2. The magnetoresistive device as claimed in claim 1, wherein an effective magnetic thickness of the synthetic antiferromagnetic layer structure is at least substantially zero.

3. The magnetoresistive device as claimed in claim 1, wherein, for the at least three ferromagnetic layers arranged one over the other, a ferromagnetic layer that is arranged proximal to the free magnetic layer structure has a magnetic thickness that is smaller than the respective magnetic thicknesses of the other ferromagnetic layers.

4. The magnetoresistive device as claimed in claim 1, wherein the synthetic antiferromagnetic layer structure further comprises
at least two antiferromagnetic coupling layers,
wherein a respective antiferromagnetic coupling layer of the at least two antiferromagnetic coupling layers is arranged between respective adjacent ferromagnetic layers of the at least three ferromagnetic layers.

5. The magnetoresistive device as claimed in claim 1, further comprising an antiferromagnetic layer configured to pin the synthetic antiferromagnetic layer structure.

6. The magnetoresistive device as claimed in claim 1, further comprising a spacer layer between the free magnetic layer structure and the synthetic antiferromagnetic layer structure.

7. The magnetoresistive device as claimed in claim 1, further comprising a cancellation layer structure configured to provide a field to compensate for a field originating from the synthetic antiferromagnetic layer structure.

8. The magnetoresistive device as claimed in claim 7, wherein the synthetic antiferromagnetic layer structure and the cancellation layer structure are arranged on opposite sides of the free magnetic layer structure.

9. The magnetoresistive device as claimed in claim 7, wherein a magnetization orientation of the cancellation layer structure is anti-parallel to the magnetization orientation of the ferromagnetic layer of the at least three ferromagnetic layers that is arranged proximal to the free magnetic layer structure.

10. The magnetoresistive device as claimed in claim 7, wherein the cancellation layer structure comprises a synthetic antiferromagnetic layer structure, the synthetic antiferomagnetic layer comprising at least two antiferromagnetically coupled ferromagnetic layers.

11. The magnetoresistive device as claimed in claim 7, further comprising a non-magnetic spacer layer between the cancellation layer structure and the free magnetic layer structure.

12. The magnetoresistive device as claimed in claim 1, further comprising a seed layer structure, wherein the free magnetic layer structure and the synthetic antiferromagnetic layer structure are arranged over the seed layer.

13. The magnetoresistive device as claimed in claim 1, further comprising a cap layer structure arranged over the free magnetic layer structure and the synthetic antiferromagnetic layer structure.

14. The magnetoresistive device as claimed in claim 1, wherein the free magnetic layer structure comprises a single magnetic layer or a bilayer structure or a multilayer structure comprising a plurality of bilayer structures.

15. The magnetoresistive device as claimed in claim 1, wherein the ferromagnetic layer that is arranged proximal to the free magnetic layer structure comprises a single magnetic layer or a bilayer structure or a multilayer structure comprising a plurality of bilayer structures.

16. The magnetoresistive device as claimed in claim 1, wherein each ferromagnetic layer has a thickness that is less than about 20 nm.

17. The magnetoresistive device as claimed in claim 1, wherein the synthetic antiferromagnetic layer structure comprises one or more further ferromagnetic layers.

18. A method for forming a magnetoresistive device, the method comprising:
forming a free magnetic layer structure having a variable magnetization orientation; and
forming a synthetic antiferromagnetic layer structure comprising at least three ferromagnetic layers arranged one over the other and antiferromagnetically coupled, each ferromagnetic layer having a fixed magnetization orientation,
wherein the free magnetic layer structure and the synthetic antiferromagnetic layer structure are arranged one over the other.

19. The method as claimed in claim 18, wherein an effective magnetic thickness of the synthetic antiferromagnetic layer structure is at least substantially zero.

20. The method as claimed in claim 18, further comprising forming a cancellation layer structure, the cancellation layer structure configured to provide a field for compensating a field originating from the synthetic antiferromagnetic layer structure.
